(19) United States
(12) Patent Application Publication
(10) Pub. No.: US 2025/0118686 A1
(43) Pub. Date: Apr. 10, 2025

(54) MEMORY DEVICE AND METHOD OF MANUFACTURING THE SAME

(71) Applicant: SK hynix Inc., Icheon-si Gyeonggi-do (KR)

(72) Inventors: Hwae Bong JUNG, Icheon-si Gyeonggi-do (KR); Jae Seok KIM, Icheon-si Gyeonggi-do (KR)

(73) Assignee: SK hynix Inc., Icheon-si Gyeonggi-do (KR)

(21) Appl. No.: 18/643,335

(22) Filed: Apr. 23, 2024

(30) Foreign Application Priority Data
Oct. 6, 2023 (KR) 10-2023-0133348

(51) Int. Cl. H01L 23/60; H01L 29/08; H01L 29/417; H10B 43/10; H10B 43/20; H10B 43/40; H10B 43/50

(52) U.S. Cl. CPC H01L 23/60; H10B 43/10; H10B 43/20; H10B 43/40; H10B 43/50; H10D 62/151; H10D 64/251

(57) ABSTRACT

A memory device, and a method of manufacturing the same, includes a discharge contact, a source pattern surrounding a periphery of the discharge contact and floated, and a source line surrounding a periphery of the source pattern and to which a source voltage is applied. The memory device also includes a separation pattern electrically isolating the source pattern and the source line, main support patterns positioned on the source pattern, sub support patterns positioned on the source line, and a contact positioned on the discharge contact.

### CROSS-REFERENCE TO RELATED APPLICATION

The present application claims priority under 35 U.S.C. § 119(a) to Korean patent application number 10-2023-0133348 filed on Oct. 6, 2023, in the Korean Intellectual Property Office, the entire contents of which application is incorporated herein by reference.

### BACKGROUND

### 1. Technical Field

The present disclosure relates to a memory device and a method of manufacturing the same, and more particularly, to a memory device including a discharge contact and a method of manufacturing the same.

### 2. Related Art

A memory device may include a memory cell array in which data is stored, peripheral circuits configured to perform a program, read, or erase operation of the memory cell array, and a control circuit configured to control the peripheral circuits.

The memory cell array may include a plurality of memory blocks. When the memory blocks are formed in a three-dimensional structure, the memory blocks may be distinguished from each other by slit regions.

The memory blocks formed in the three-dimensional structure may include a stack structure stacked in a vertical direction from a substrate. The stack structure may include a plurality of gate lines and insulating layers alternately stacked. The memory blocks may be divided into a cell region in which the memory cells are included and a connection region in which contacts are included. For example, in a structure in which the memory cell array is stacked on the peripheral circuit, the peripheral circuit and the memory cell array may be electrically connected through the contacts included in the connection region.

A discharge contact for removing dummy ions that may occur during a manufacturing process of the memory device may be positioned in the connection region. A source line may be positioned around the discharge contact. The discharge contact may be formed of a conductive material to discharge the dummy ions. Therefore, the discharge contact is required to be spaced apart from the source line.

When a distance between the source line and the discharge contact is much shorter than a reference distance, a bridge may occur between the source line and the discharge contact during a manufacturing step of the memory device. When the distance between the source line and the discharge contact is much longer than the reference distance, a size of the memory device may increase.

### SUMMARY

According to an embodiment of the present disclosure, a memory device includes a discharge contact, a source pattern surrounding a periphery of the discharge contact and floated, a source line surrounding a periphery of the source pattern and to which a source voltage is applied, a separation pattern electrically isolating the source pattern and the source line, main support patterns positioned on the source pattern, sub support patterns positioned on the source line, and a contact positioned on the discharge contact.

According to an embodiment of the present disclosure, a memory device includes an open region insulating layer extending in a first direction, a discharge contact included in the open region insulating layer, a source pattern surrounding an outer surface of the open region insulating layer, a separation pattern surrounding an outer surface of the source pattern, and a source line surrounding an outer surface of the separation pattern.

According to an embodiment of the present disclosure, a method of manufacturing a memory device may include stacking source layers on a lower structure, separating the source layers into a source pattern and a preliminary pattern, forming a separation pattern between the source pattern and the preliminary pattern, forming a discharge contact contacting the lower structure in a region spaced apart from the source pattern, forming a main support pattern positioned on the source pattern and a sub support pattern positioned on the preliminary pattern, and forming the preliminary pattern as a source line.

### BRIEF DESCRIPTION OF THE DRAWINGS

FIG. 1 is a diagram illustrating a memory device.

FIG. 2 is a diagram illustrating a peripheral circuit and a memory cell array.

FIG. 3 is a layout illustrating an arrangement of a discharge contact and support patterns according to an embodiment of the present disclosure.

FIG. 4 is a layout illustrating a discharge contact, a source pattern, and a source line according to an embodiment of the present disclosure.

FIG. 5 is a cross-sectional view illustrating a memory device according to an embodiment of the present disclosure.

FIGS. 6A to 6O are diagrams illustrating a method of manufacturing a memory device according to an embodiment of the present disclosure.

FIG. 7 is a diagram illustrating a memory card system to which a memory device of the present disclosure is applied.

FIG. 8 is a diagram illustrating a solid-state drive (SSD) system to which a memory device of the present disclosure is applied.

### DETAILED DESCRIPTION

Specific structural or functional descriptions disclosed below are exemplified to describe an embodiment according to the concept of the present disclosure. The embodiment according to the concept of the present disclosure is not construed as being limited to the embodiments described below, and may be variously modified and replaced with other equivalent embodiments.

Hereinafter, terms such as first and second may be used to describe various components, but the components are not limited by the terms. The terms are used for the purpose of distinguishing one component from another component rather than implying a number or order of components.

An embodiment of the present disclosure provides a memory device and a method of manufacturing the same capable of preventing a reduction in a size of a discharge contact and securing a margin between a source line and the discharge contact. The present technology may reduce a resistance of the discharge contact by preventing a reduction in a size of the discharge contact. The present technology may prevent a bridge from occurring between the source line and the discharge contact by securing a margin between the source line and the discharge contact.

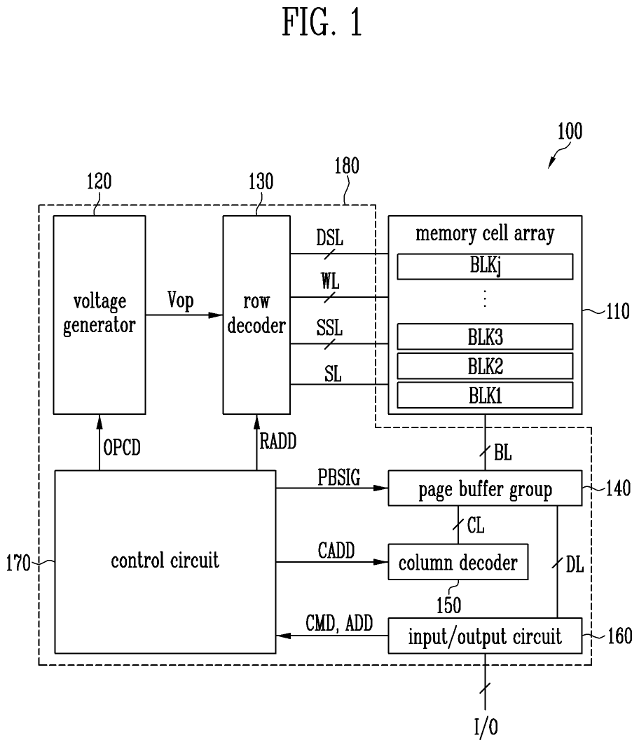

FIG. 1 is a diagram illustrating a memory device.

Referring to FIG. 1, the memory device 100 may include a memory cell array 110 and a peripheral circuit 180.

The memory cell array 110 may include first to j-th memory blocks BLK1 to BLKj. Each of the first to j-th memory blocks BLK1 to BLKj may include memory cells capable of storing data. Drain select lines DSL, word lines WL, source select lines SSL, and a source line SL may be connected to each of the first to j-th memory blocks BLK1 to BLKj, and a bit line BL may be commonly connected to the first to j-th memory blocks BLK1 to BLKj.

The first to j-th memory blocks BLK1 to BLKj may be formed in a three-dimensional structure. The memory blocks having the three-dimensional structure may include memory cells stacked on a substrate in a vertical direction.

The memory cells may store 1 bit or 2 bits or more of data according to a program method. For example, a method in which 1 bit of data is stored in one memory cell is referred to as a single-level cell method, and a method in which 2 bits of data is stored in one memory cell is referred to as a multi-level cell method. A method in which 3 bits of data is stored in one memory cell is referred to as a triple-level cell method, and a method in which 4 bits of data is stored in one memory cell is referred to as a quad-level cell method. In addition to this, five bits or more of data may be stored in one memory cell.

The peripheral circuit 180 may be configured to perform the program operation of storing data in the memory cell array 110, the read operation of outputting the data stored in the memory cell array 110, and the erase operation of erasing the data stored in the memory cell array 110. For example, the peripheral circuit 180 may include a voltage generator 120, a row decoder 130, a page buffer group 140, a column decoder 150, an input/output circuit 160, and a control circuit 170.

The voltage generator 120 may generate various operation voltages Vop used for the program operation, the read operation, or the erase operation in response to an operation code OPCD. For example, the voltage generator 120 may be configured to generate program voltages, turn-on voltages, turn-off voltages, negative voltages, precharge voltages, verify voltages, read voltages, pass voltages, or erase voltages in response to the operation code OPCD. The operation voltages Vop generated by the voltage generator 120 may be applied to the drain select lines DSL, the word lines WL, the source select lines SSL, and the source line SL of memory block selected through the row decoder 130.

The program voltages may be voltages applied to a selected word line among the word lines WL during the program operation, and may be used to increase a threshold voltage of memory cells connected to the selected word line. The turn-on voltages may be applied to the drain select lines DSL or the source select lines SSL, and may be used to turn on drain select transistors or source select transistors. The turn-off voltages may be applied to the drain select lines DSL or the source select lines SSL, and may be used to turn off the drain select transistors or the source select transistors. For example, the turn-off voltage may be set to 0V. The precharge voltages may be a voltage higher than 0V, and may be applied to bit lines during the read operation. The verify voltages may be used during a verify operation for determining whether a threshold voltage of selected memory cells is increased to a target level. The verify voltages may be set to various levels according to the target level, and may be applied to the selected word line.

The read voltages may be applied to the selected word line during the read operation of the selected memory cells. For example, the read voltages may be set to various levels according to a program method of the selected memory cells. The pass voltages may be voltages applied to unselected word lines among the word lines WL during the program or read operation, and may be used to turn on memory cells connected to the unselected word lines.

The erase voltages may be used during the erase operation for erasing memory cells included in the selected memory block, and may be applied to the source line SL.

The row decoder 130 may be configured to transmit the operation voltages Vop to the drain select lines DSL, the word lines WL, the source select lines SSL, and the source line SL connected to the selected memory block according to a row address RADD. For example, the row decoder 130 may be connected to the voltage generator 120 through global lines, and may be connected to the first to j-th memory blocks BLK1 to BLKj through the drain select lines DSL, the word lines WL, the source select lines SSL, and the source line SL.

The page buffer group 140 may include page buffers PB1 to PBn (not shown) connected to the first to j-th memory blocks BLK1 to BLKj. Each of the page buffers (not shown) may be connected to the first to j-th memory blocks BLK1 to BLKj through the bit lines BL. During the read operation, the page buffers (not shown) may sense a current or a voltage of the bit lines which varies according to threshold voltages of the selected memory cells, and temporarily store the sensed data, in response to page buffer control signals PBSIG.

The column decoder 150 may be configured so that data is transmitted between the page buffer group 140 and the input/output circuit 160 in response to a column address CADD. For example, the column decoder 150 may be connected to the page buffer group 140 through column lines CL and may transmit enable signals through the column lines CL. The page buffers (not shown) included in the page buffer group 140 may receive or output the data through data lines DL in response to the enable signals.

The input/output circuit 160 may be configured to receive or output a command CMD, an address ADD, or data through input/output lines I/O. For example, the input/output circuit 160 may transmit the command CMD and the address ADD received from an external controller to the control circuit 170 through the input/output lines I/O, and transmit the data received from the external controller to the page buffer group 140 through the input/output lines I/O. Alternatively, the input/output circuit 160 may output the data received from the page buffer group 140 to the external controller through the input/output lines I/O.

The control circuit 170 may output the operation code OPCD, the row address RADD, the page buffer control signals PBSIG, and the column address CADD in response to the command CMD and the address ADD. For example, when the command CMD input to the control circuit 170 is a command corresponding to the program operation, the control circuit 170 may control the peripheral circuit 180 to perform the program operation of a memory block selected by the address ADD. When the command CMD input to the control circuit 170 is a command corresponding to the read operation, the control circuit 170 may control the peripheral circuit 180 to perform the read operation of the memory block selected by the address and output the read data. When the command CMD input to the control circuit 170 is a command corresponding to the erase operation, the control circuit 170 may control the peripheral circuit 180 to perform the erase operation of the selected memory block.

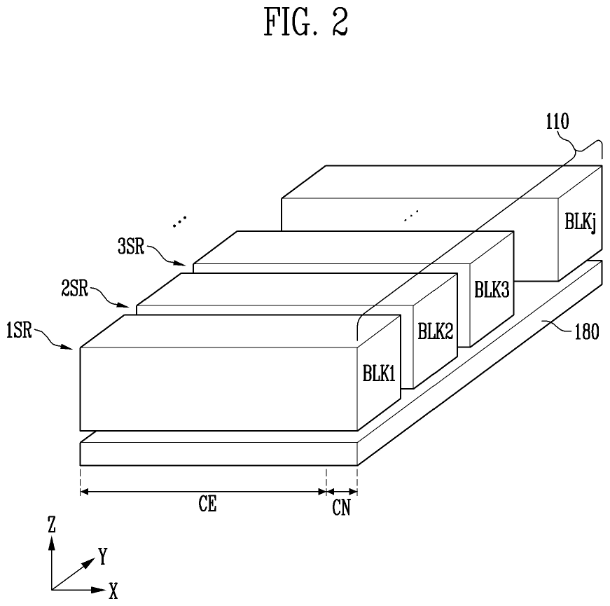

FIG. 2 is a diagram illustrating the peripheral circuit and the memory cell array.

Referring to FIG. 2, the memory cell array 110 may be positioned on the peripheral circuit 180. For example, the peripheral circuit 180 may be positioned on one substrate, and the memory cell array 110 may be positioned on the peripheral circuit 180. Alternatively, the peripheral circuit 180 and the memory cell array 110 may be formed on different substrates and then contact each other.

The memory cell array 110 may include first to j-th memory blocks BLK1 to BLKj. The first to j-th memory blocks BLK1 to BLKj may be disposed to be spaced apart from each other along a Y direction. The first to j-th memory blocks BLK1 to BLKj may be configured identically to each other and may be distinguished from each other by slit regions 1SR, 2SR, 3SR, . . . . Each of the slit regions 1SR, 2SR, 3SR, . . . may extend along an X direction. For example, the first memory block BLK1 may be positioned between first and second slit regions 1SR and 2SR, and the second memory block BLK2 may be positioned between second and third slit regions 2SR and 3SR. The first and second memory blocks BLK1 and BLK2 may be separated from each other by the second slit region 2SR.

Each of the first to j-th memory blocks BLK1 to BLKj may include a cell region CE and a connection region CN. Memory cells configured to store data may be positioned in the cell region CE, and a plurality of connection structures connected to the peripheral circuit 180 may be positioned in the connection region CN. For example, the connection structures may include contacts, lines, support patterns, and discharge contacts. The contact may be configured to contact gate lines extending from the cell region CE or to contact the peripheral circuit 180 positioned under the memory cell array 110. The lines may be configured to electrically connect the contacts. The support patterns may be configured to support a stack structure positioned in the connection region CN. The discharge contacts may be configured to discharge dummy ions that may occur during a manufacturing process of the memory device to a ground terminal. For example, the dummy ions may mainly occur during an etching process. When the dummy ions remain in a partial region of the memory device, reliability of operations may be reduced due to the dummy ions during the program, read, or erase operation of the memory device. Therefore, the discharge contacts may discharge the dummy ions that may occur during the manufacturing process of the memory device through the ground terminal.

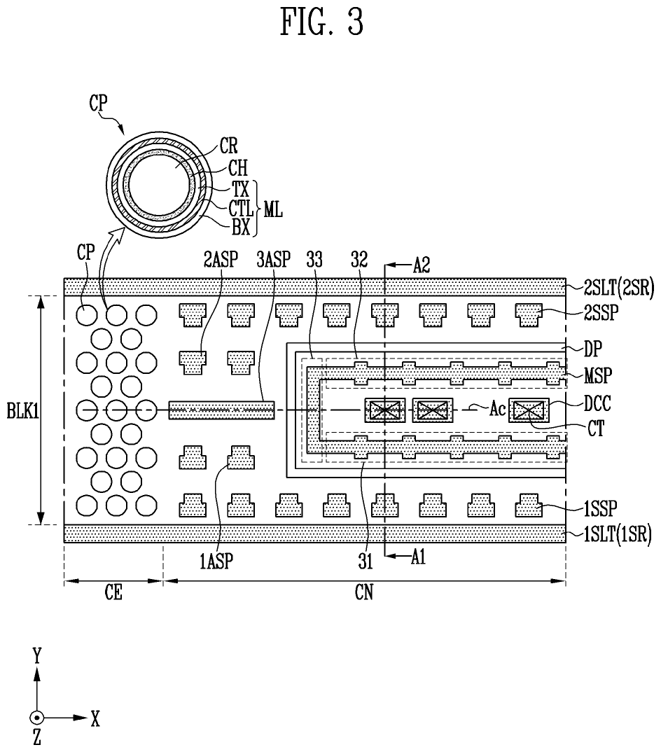

FIG. 3 is a layout illustrating an arrangement of discharge contacts and support patterns according to an embodiment of the present disclosure.

Referring to FIG. 3, a layout of the first memory block BLK1 among the first to j-th memory blocks BLK1 to BLKj shown in FIG. 2 is shown.

The first memory block BLK1 may be positioned between first and second slit structures 1SLT and 2SLT. The first slit structure 1SLT may be formed in a first slit region 1SR, and the second slit structure 2SLT may be formed in a second slit region 2SR. The first and second slit structures 1SLT and 2SLT may be formed of an insulating material or a conductive material, or may be formed of an insulating material and a conductive material.

The first memory block BLK1 may be divided into the cell region CE and the connection region CN.

Cell plugs CP including memory cells may be positioned between the first and second slit structures 1SLT and 2SLT of the cell region CE. Each of the cell plugs CP may include a core pillar CR, a channel layer CH, and a memory layer ML configuring memory cells or select transistors. The memory layer ML may include a tunnel isolation layer TX, a charge trap layer CTL, and a blocking layer BX. The core pillar CR may have a cylindrical shape and may be formed of an insulating material or a conductive material. The channel layer CH may have a cylindrical shape surrounding a side surface of the core pillar CR and may be formed of polysilicon. The tunnel insulating layer TX may have a cylindrical shape surrounding a side surface of the channel layer CH and may be formed of an oxide layer. The charge trap layer CTL may have a cylindrical shape surrounding a side surface of the tunnel insulating layer TX and may be formed of a nitride layer. The blocking layer BX may have a cylindrical shape surrounding a side surface of the charge trap layer CTL and may be formed of an oxide layer. Assuming that the first and second slit structures 1SLT and 2SLT extend along the X direction and are spaced apart from each other along the Y direction, the cell plugs CP may be arranged to be spaced apart from each other along the X and Y directions.

First and second sub support patterns 1SSP and 2SSP, first to third assistance support patterns 1ASP to 3ASP, a separation pattern DP, a main support pattern MSP, discharge contacts DCC, and contacts CT may be positioned between the first and second slit structures 1SLT and 2SLT of the connection region CN. The first and second sub support patterns 1SSP, 2SSP, the first to third assistance support patterns 1ASP to 3ASP, and the main support pattern MSP may be configured to support the stack structure configuring the memory block and may be formed of an insulating material. For example, the insulating material may be an oxide material, and more specifically, a silicon oxide material. The first and second sub support patterns 1SSP and 2SSP may be positioned between the first and second slit structures 1SLT and 2SLT and may be spaced apart from the first and second slit structures 1SLT and 2SLT. The first sub support patterns 1SSP may be spaced apart from each other along the X direction in a region adjacent to the first slit structure 1SLT. The second sub support patterns 2SSP may be spaced apart from each other along the X direction in a region adjacent to the second slit structure 2SLT.

The first and second assistance support patterns 1ASP and 2ASP may be positioned in a region close to the cell region CE between the first and second sub support patterns 1SSP and 2SSP. The first assistance support patterns 1ASP may be arranged along the X direction, and the second assistance support patterns 2ASP may also be arranged along the X direction. The third assistance support pattern 3ASP may be formed in a linear shape extending in the X direction between the first and second assistance support patterns 1ASP and 2ASP.

The first and second sub support patterns 1SSP and 2SSP and the first and second assistance support patterns 1ASP and 2ASP may be formed in an island shape spaced apart from each other. For example, a plane of each of the first and second sub support patterns 1SSP and 2SSP and the first and second assistance support patterns 1ASP and 2ASP may be a quadrangular shape or a circular shape, and may have a shape of which a portion protrudes. For example, assuming that an axis extending in the X direction between the first and second slit structures 1SLT and 2SLT is a central axis Ac, a protrusion of each of the first and second sub support patterns 1SSP and 2SSP and the first and second assistance support patterns 1ASP and 2ASP may protrude in a direction toward the central axis Ac, as pictured.

The main support pattern MSP may be positioned between the first and second sub support patterns 1SSP and 2SSP. The main support pattern MSP may be formed in a linear shape connected to each other. For example, the main support pattern MSP may include patterns 31 and 32 extending in the X direction and arranged in parallel and a pattern 33 connecting the patterns 31 and 32 arranged in parallel in the Y direction. The pattern 33 is positioned in a region adjacent to the third assistance support pattern 3ASP, and does not contact the third assistance support pattern 3ASP. Protrusions for improving a support function may be included in a portion of the patterns 31 and 32 extending in the ±Y direction.

The contacts CT and the discharge contacts DCC may be positioned in a region surrounded by the main support pattern MSP. The contacts CT and the discharge contacts DCC may be formed of a conductive material. The contacts CT may be stacked in a Z direction from the discharge contacts DCC. Therefore, in a plan view, the contacts CT overlap the discharge contacts DCC. The contacts CT may electrically connect structures spaced apart from each other in the Z direction. Although not shown in the drawing, the contacts CT may also be positioned in a region adjacent to the first or second sub support patterns 1SSP or 2SSP in addition to the region surrounded by the main support pattern MSP.

The discharge contacts DCC are a structure for removing the dummy ions that may occur during the manufacturing process of the memory device through the ground terminal. The dummy ions may mainly occur during a dry etching process. For example, the dry etching process may be mainly performed in a reactive ion etching (RIE) method or a method applying the RIE method. Plasma is used in the etching process of the RIE method or the method applying the RIE method. Positive ions generated by the plasma may collide with an etching target layer, and thus bonding force of a surface of the etching target layer may be weakened. Molecules of a portion where the bonding force is weakened in the etching target layer may be discharged to an outside of a chamber together with a radical. At this time, some positive ions may remain in the etching target layer. The remaining positive ions may become the dummy ions and may affect an operation of the memory device after manufacturing of the memory device is completed. Therefore, the discharge contacts DCC may be positioned in a region where the dummy ions remain and may be electrically connected to ground terminals. The dummy ions may be discharged through the discharge contacts DCC and the ground terminals and may be removed from the memory device.

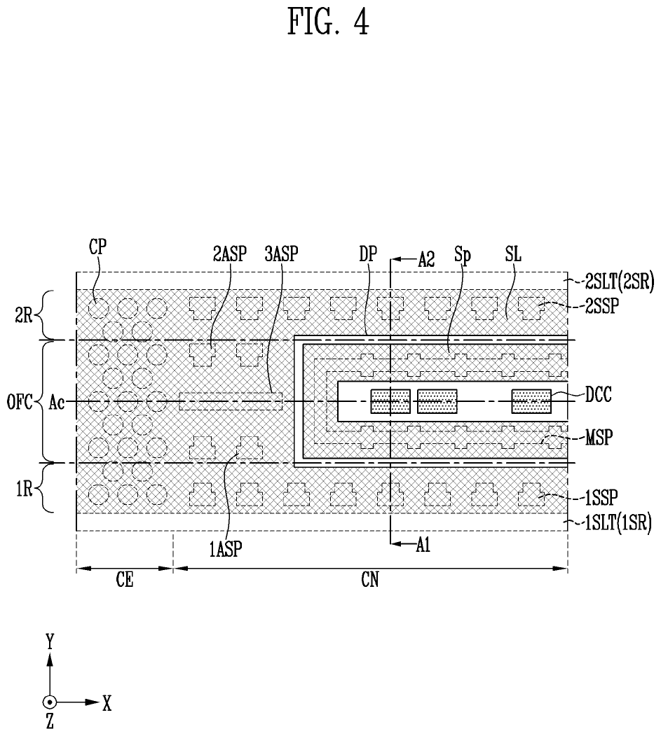

The separation pattern DP may be formed around the main support pattern MSP. The separation pattern DP is a structure for separating a source line positioned in the connection region CN. Therefore, the separation pattern DP may be formed of an insulating material. For example, the insulating material configuring the separation pattern DP may be an oxide material, and specifically, may be a silicon oxide material. The separation pattern DP may be a pattern for dividing a partial source line adjacent to the discharge contacts DCC into a source pattern among the source line extending in the cell region CE and the connection region CN. The source line and the source pattern divided by the separation pattern DP are specifically described with reference to FIG. 4.

FIG. 4 is a layout illustrating a discharge contact, a source pattern, and a source line according to an embodiment of the present disclosure.

Referring to FIG. 4, the cell region CE and the connection region CN may be divided into a first region 1R, an open contact region OFC, and a second region 2R along the Y direction. The open contact region OFC may be positioned between the first and second regions 1R and 2R.

The source line SL may be a conductive material and may extend from the cell region CE to the connection region CN. The source line SL of the cell region CE may be electrically connected to the cell plugs CP, and the source line SL of the connection region CN may contact the first and second sub support patterns 1SSP and 2SSP and the first to third assistance support patterns 1ASP to 3ASP. Because the first and second sub support patterns 1SSP and 2SSP and the first to third assistance support patterns 1ASP to 3ASP positioned in the connection region CN are formed of an insulating material, the first and second sub support patterns 1SSP and 2SSP and the first to third assistance support patterns 1ASP to 3ASP positioned in the connection region CN may not electrically contact the source line SL. In the connection region CN, the source line SL may be positioned outside the separation pattern DP.

The source pattern Sp may be positioned in a region surrounded by the separation pattern DP. The source pattern Sp may be separated from the source line SL by the separation pattern DP. For example, the source pattern Sp may be positioned in the open contact region OFC. The source line SL and the source pattern Sp may be symmetrical to each other about the central axis Ac. Because the separation pattern DP is formed of an insulating material, the source pattern Sp and the source line SL may be electrically isolated from each other. The source line SL may be electrically connected to the cell plugs CP positioned in the cell region CE and may transfer a source voltage generated by the voltage generator to the cell plugs CP.

The source pattern Sp may be positioned between the separation pattern DP and the discharge contacts DCC and may be electrically floated. The source pattern Sp is in contact with the separation pattern DP and is spaced apart from the discharge contacts DCC. Therefore, an insulating material may be filled between the source pattern Sp and the discharge contacts DCC. The source pattern Sp may be used as an etch stop layer during a manufacturing process of the main support pattern MSP. Even though a bridge occurs between the source pattern Sp and the discharge contacts DCC, because the source pattern Sp and the source line SL are electrically isolated from each other by the separation pattern DP, the discharge contacts DCC and the source line SL are not electrically connected. Accordingly, because a distance between the discharge contacts DCC and the source pattern Sp may be reduced, a size of each of the discharge contacts DCC may be increased or a size of the memory device may be reduced.

A structure of the connection region is specifically described with reference to a cross-sectional view of FIG. 3 or FIG. 4 cut an A1-A2 direction as follows.

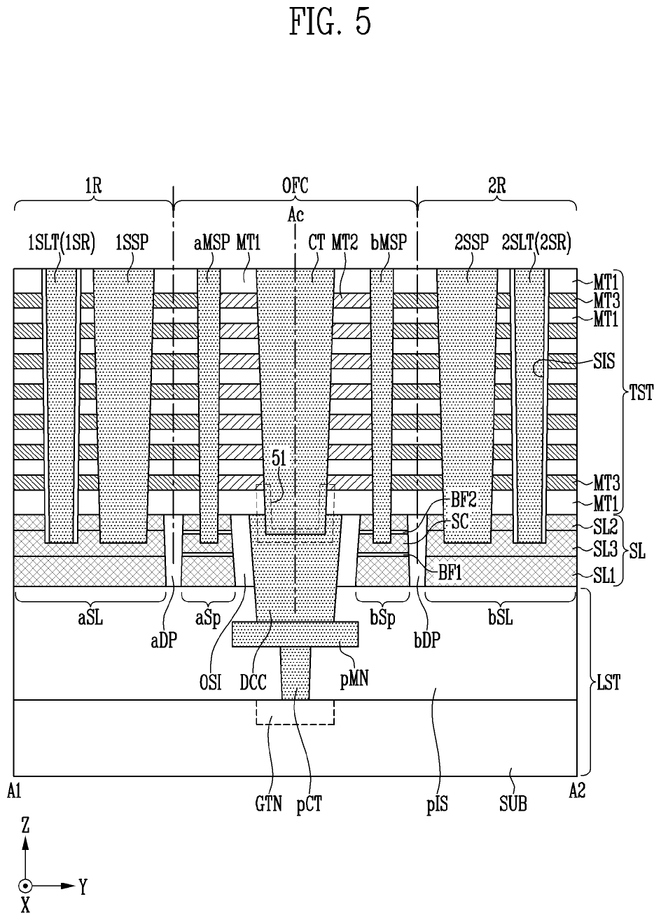

FIG. 5 is a cross-sectional view illustrating a memory device according to an embodiment of the present disclosure.

Referring to FIG. 5, the source line SL and an upper structure TST may be positioned on a lower structure LST. The lower structure LST may include a substrate SUB and peripheral circuit structures pCT, pMN, and DCC.

The substrate SUB may be a silicon substrate and may include a ground terminal GTN. The ground terminal GTN may be a junction where an impurity is injected into the substrate SUB, or may be a line formed of a conductive material. A ground voltage may be supplied to the ground terminal GTN. The peripheral circuit structures pCT, pMN, and DCC may include a peripheral contact pCT, a peripheral line pMN, and the discharge contact DCC. A peripheral insulating layer pIS may be filled around the peripheral contact pCT, the peripheral line pMN, and the discharge contact DCC. The peripheral contact pCT may be positioned on the ground terminal GTN and may be formed of a conductive material. The peripheral line pMN may be positioned on the ground contact pCT and may be formed of a conductive material. The peripheral line pMN may have a width wider than that of the peripheral contact pCT.

The discharge contact DCC may be positioned on the peripheral contact pMN and may be formed of a conductive material. Therefore, the discharge contact DCC may be electrically connected to the peripheral line pMN, the peripheral contact pCT, and the ground terminal GTN. The discharge contact DCC may be configured to discharge the dummy ions that may occur during the manufacturing process of the memory device through the ground terminal GTN. The dummy ions may mainly occur during a dry etching process. For example, the dry etching process may be mainly performed in an RIE method or a method applying the RIE method. Plasma is used in the etching process of the RIE method or the method applying the RIE method. Positive ions generated by the plasma may collide with an etching target layer, and thus bonding force of a surface of the etching target layer may be weakened. Molecules of a portion where the bonding force is weakened in the etching target layer may be discharged to an outside of a chamber together with a radical. At this time, some positive ions may remain around 51 the etching target layer. The remaining positive ions may become the dummy ions and may affect an operation of the memory device after manufacturing of the memory device is completed. Therefore, the discharge contacts DCC may be positioned in a region where the dummy ions remain, and the dummy ions may be discharged through the discharge pattern DCC, the peripheral line pMN, the peripheral contact pCT, and the ground terminal GTN and may be removed from the memory device.

The source line SL may include first to third source layers SL1 to SL3, a sacrificial layer SC, and first and second buffer layers BF1 and BF2. The first to third source layers SL1 to SL3 may be positioned in the first and second regions 1R and 2R, and the first and second source layers SL1 and SL2, the sacrificial layer SC, and the first and second buffer layers BF1 and BF2 may be positioned in the open contact region OFC. The first and second regions 1R and 2R may be divided along the Y direction about the central axis Ac of the A1-A2 cross section. For example, a portion of a region left from the central axis Ac may be defined as the first region 1R, and a portion of a region right from the central axis Ac may be defined as the second region 2R. The open contact region OFC may be defined as a region between the first and second regions 1R and 2R. For example, the open contact region OFC may be defined by first and second separation patterns aDP and bDP. The first separation pattern aDP may distinguish the first region 1R and the open contact region OFC, and the second separation pattern bDP may distinguish the second region 2R and the open contact region OFC.

The first and second separation patterns aDP and bDP may be formed of an insulating material. Therefore, the first and second source layers SL and SL2 included in the open contact region OFC may be electrically isolated from the first and second source layers SL1 and SL2 included in the first and second regions 1R and 2R. During a program, read, or erase operation of the memory device, the source voltage may be applied to the first to third source layers SL1 to SL3 included in the first and second regions 1R and 2R, and the first and second source layers SL and SL2 included in the open contact region OFC may be floated. The first and second buffer layers BF1 and BF2 and the sacrificial layer SC may be positioned between the first and second source layers SL and SL2 of the open contact region OFC. For example, the first buffer layer BF1 may be positioned on the first source layer SL1, the sacrificial layer SC may be positioned on the first buffer layer BF1, the second buffer layer BF2 may be positioned on the sacrificial layer SC, and the second source layer SL2 may be positioned on the second buffer layer BF2. The first and second source layers SL1, SL2, the first and second buffer layers BF1, BF2, and sacrificial layer SC positioned on the left from the central axis Ac may become a first source pattern aSp. The first and second source layers SL1, SL2, the first and second buffer layers BF1, BF2, and sacrificial layer SC positioned on the right from the central axis Ac may become a second source pattern bSp. The first source pattern aSp may be positioned between the first separation pattern aDP and an open region insulating layer OSI, and the second source pattern bSp may be positioned between the second separation pattern bDP and the open region insulating layer OSI.

The open region insulating layer OSI may be formed between the first and second source patterns aSp and bSp, and the discharge contact DCC passing through a center of the open region insulating layer OSI may be positioned. The discharge contact DCC may protrude into the lower structure LST by passing through the open region insulating layer OSI, and the protruding portion may be in contact with the peripheral line pMN of the lower structure LST.

The upper structure TST positioned on the source line SL may include first to third material layers MT1 to MT3, first and second slit structures 1SLT and 2SLT, slit insulating layers SIS, first and second sub support patterns 1SSP and 2SSP, first and second main support patterns aMSP and bMSP, and a contact CT.

The first and third material layers MT1 and MT3 may be alternately stacked in the first and second regions 1R and 2R, and the first and second material layers MT1 and MT2 may be alternately stacked in the open contact region OFC. A portion of the first and third material layers MT1 and MT3 of the first and second regions 1R and 2R may extend into the open contact region OFC.

The first slit structure 1SLT may protrude into the source line SL by passing through the first and third material layers MT1 and MT3 of the first region 1R, and the second slit structure 2SLT may protrude into the source line SL by passing through the first and third material layers MT1 and MT3 of the second region 2R. The first and second slit structures 1SLT and 2SLT protruding to the source line SL may contact the source line SL. The first and second slit structures 1SLT and 2SLT may be formed of a conductive material or an insulating material. A slit insulating layer SIS surrounding a side surface of the first and second slit structures 1SLT and 2SLT may be further formed. The slit insulating layer SIS may be an oxide layer. For example, the slit insulating layer SIS may be a silicon oxide layer.

The first main support pattern aMSP may be positioned between the second material layers MT2 and the third material layers MT3 in the open contact region OFC, and the second main support pattern bMSP may be positioned between the second material layers MT2 and the third material layers MT3 in the open contact region OFC. For example, the first main support pattern aMSP may contact the first source pattern aSp by passing through the first to third material layers MT1 to MT3, and the second main support pattern bMSP may contact the second source pattern bSp by passing through the first to third material layers MT1 to MT3. The first and second main support patterns aMSP and bMSP may be formed of an insulating material.

The contact CT may contact the discharge contact DCC by passing through the first and second material layers MT1 and MT2 of the open contact region OFC. The contact CT may be formed of a conductive material. Therefore, the contact CT, the discharge contact DCC, the peripheral line pMN, the peripheral contact pCT, and the ground terminal GTN positioned along the central axis Ac may be electrically connected to each other.

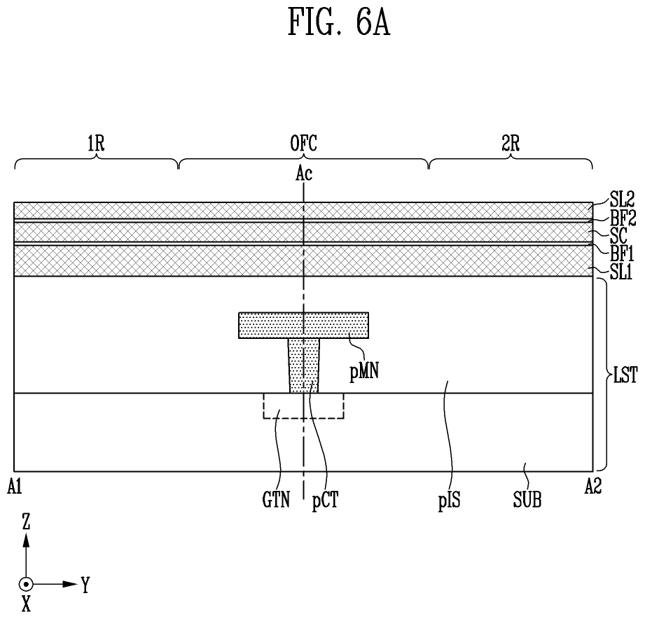

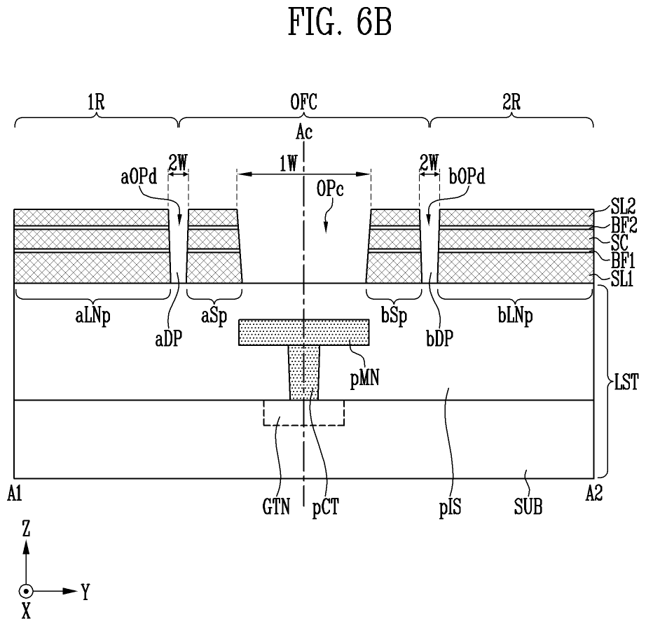

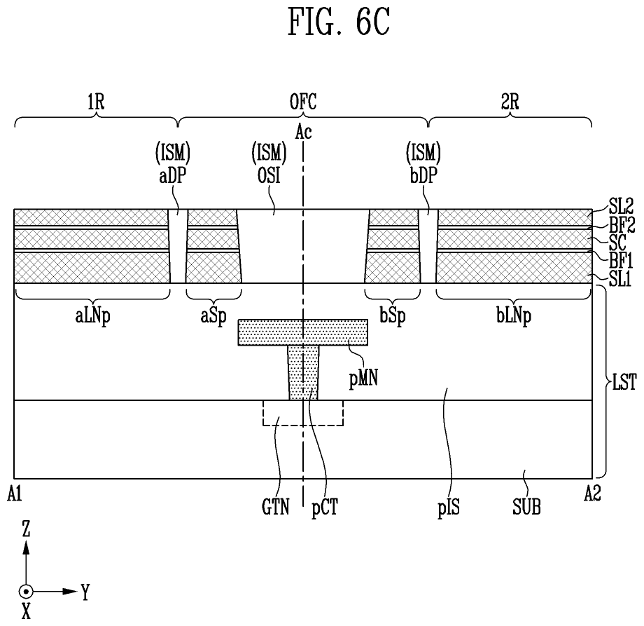

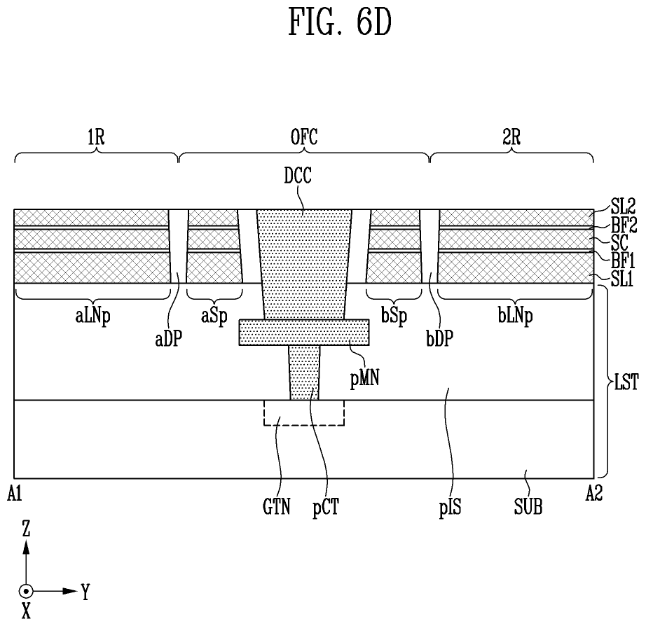

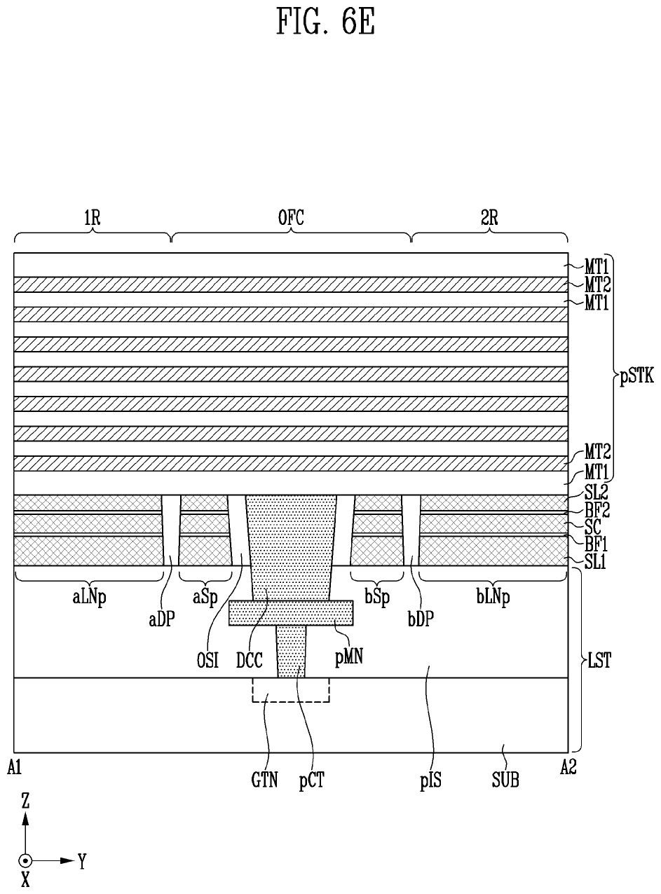

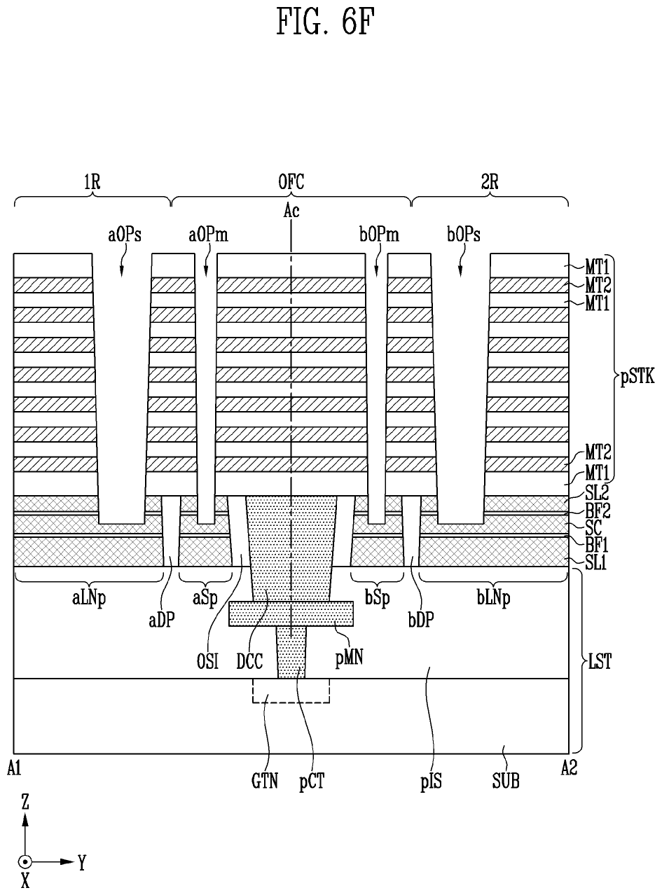

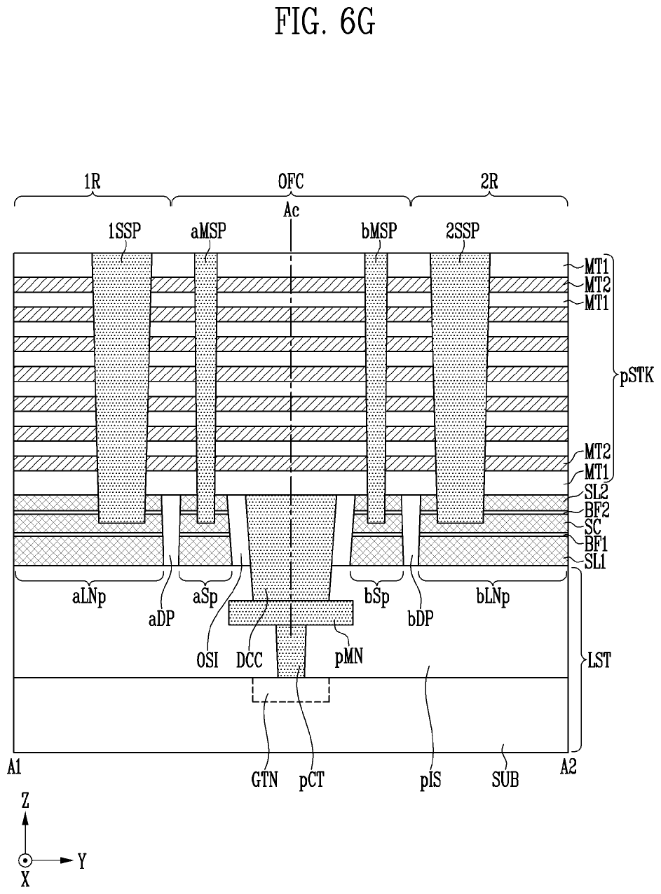

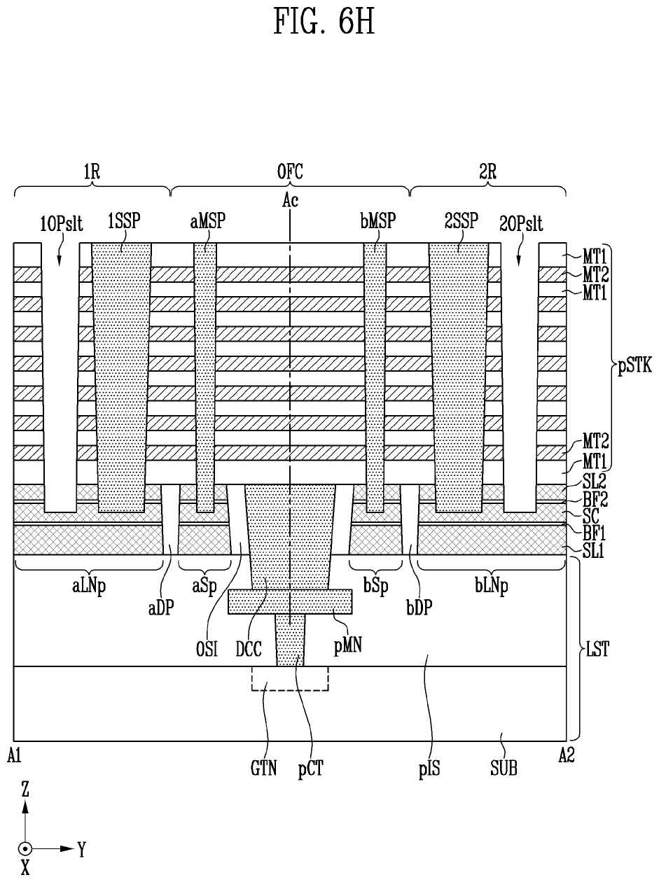

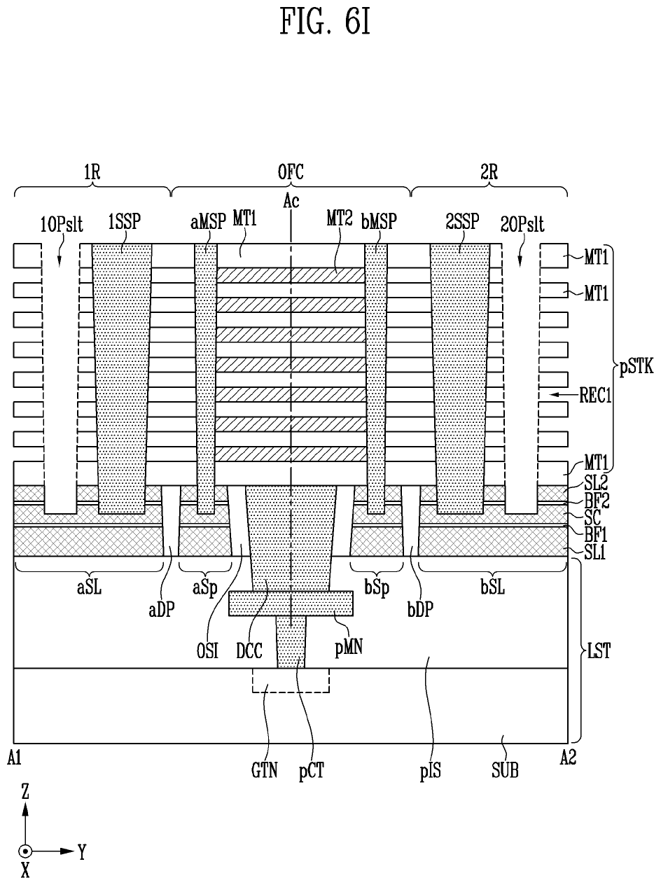

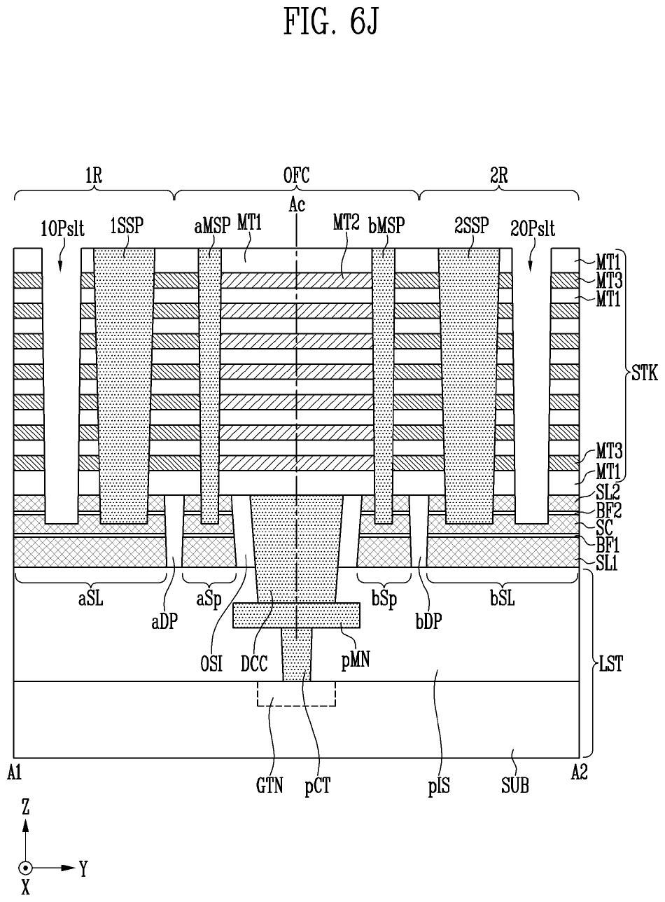

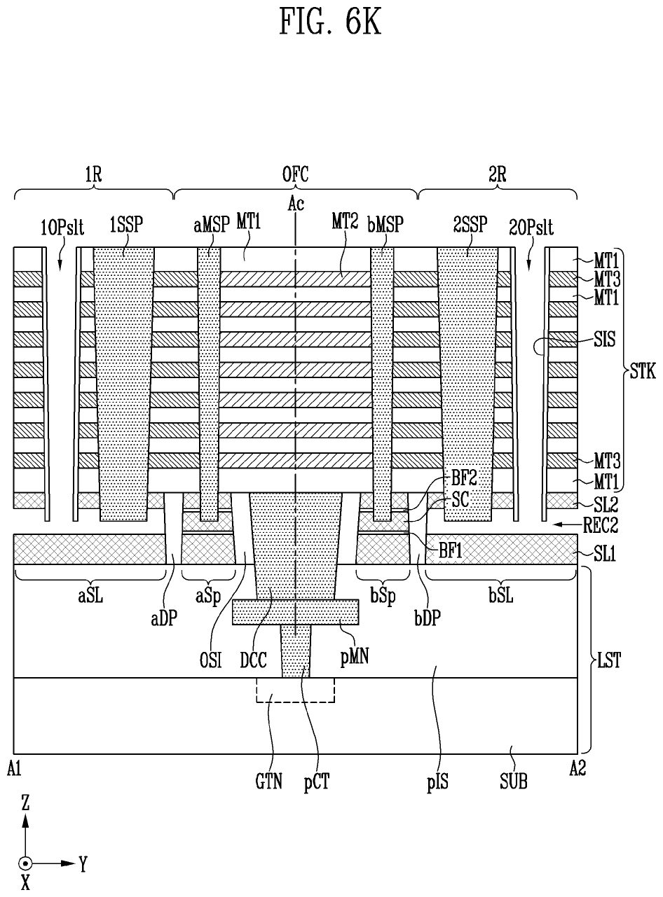

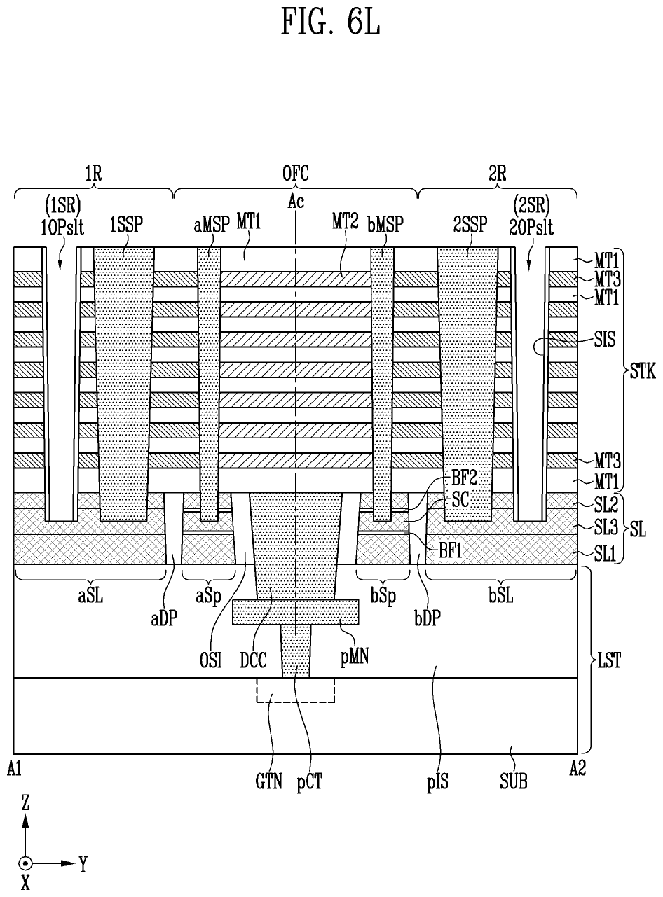

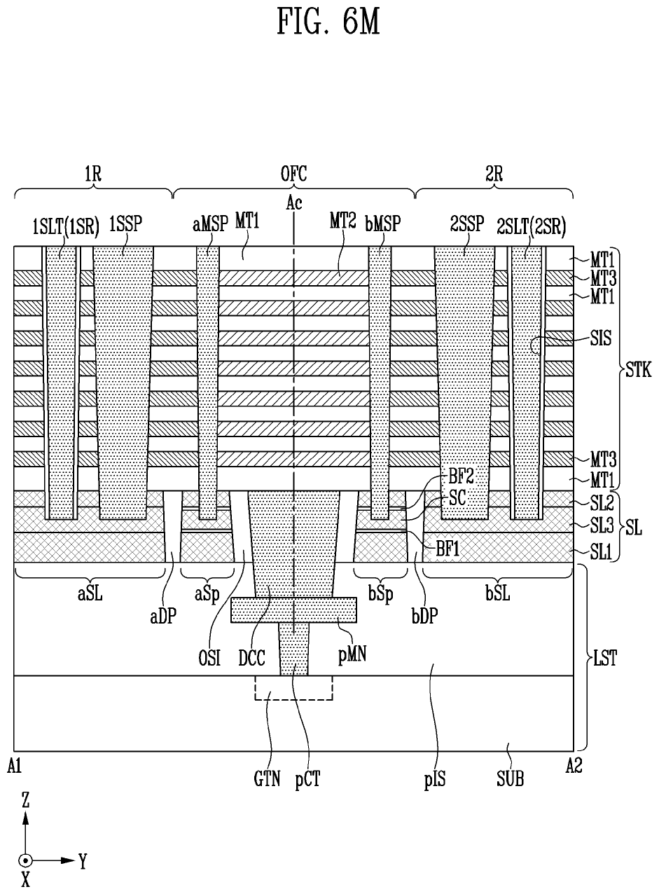

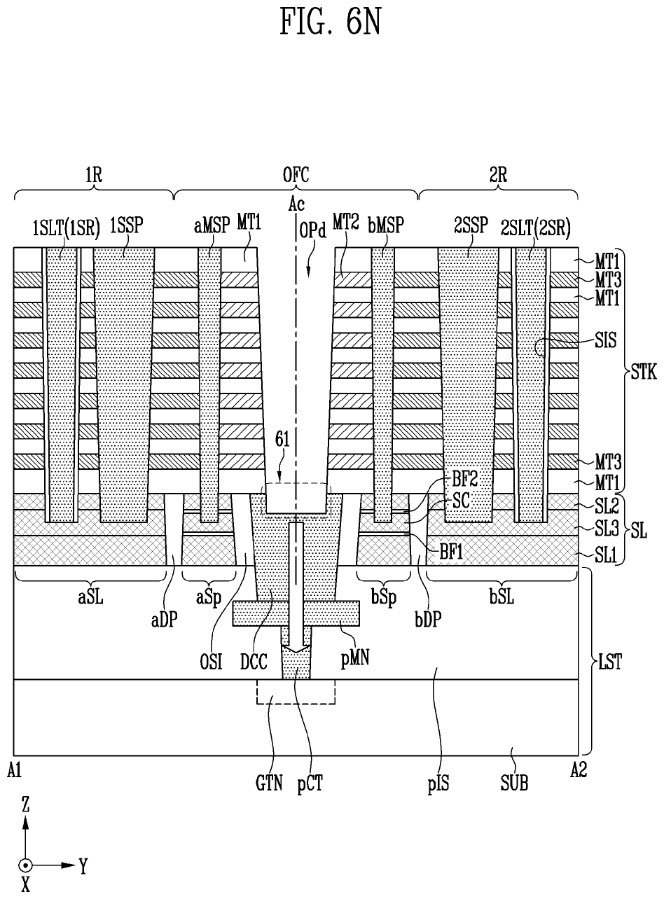

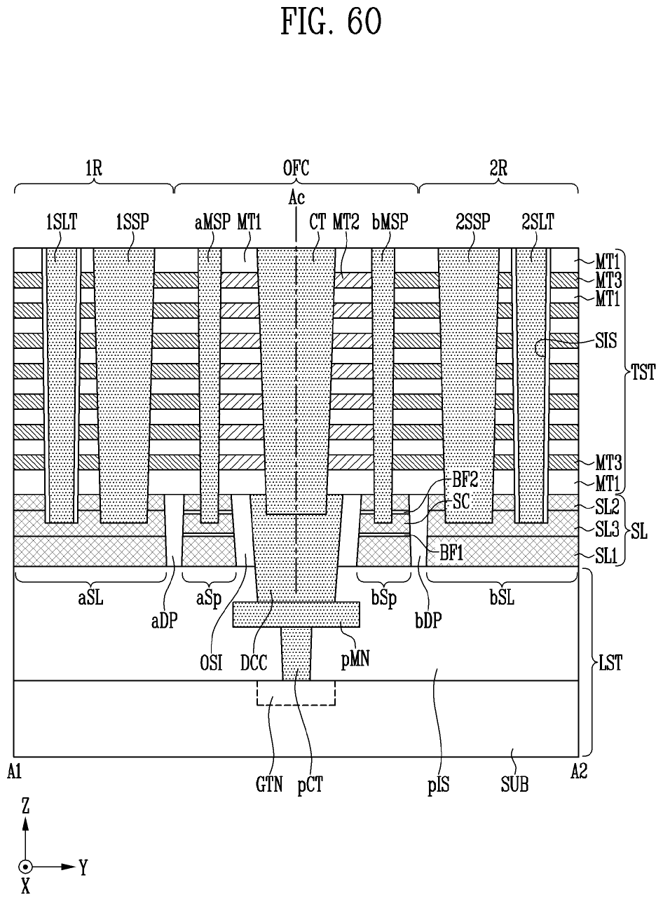

FIGS. 6A to 6O are diagrams illustrating a method of manufacturing a memory device according to an embodiment of the present disclosure.

Referring to FIG. 6A, the ground terminal GTN may be formed on the substrate SUB on which the open contact region OFC is defined. The contact open region OFC may be a region where structures for electrically connecting the upper structure TST of FIG. 5 and the lower structure LST are positioned, and may be positioned between the first and second regions 1R and 2R. The ground terminal GTN may be formed by doping the substrate SUB with an impurity, or may be formed by forming a trench in the substrate SUB and filling the trench with a conductive material. The ground terminal GTN may be connected to a terminal to which the ground voltage is supplied.

The peripheral contact pCT, the peripheral line pMN, and the peripheral insulating layer pIS may be formed on the substrate SUB. The peripheral contact pCT may be positioned on the ground terminal GTN, and the peripheral line pMN may be positioned on the peripheral contact pCT. The peripheral contact pCT may have a width narrower than that of the ground terminal GTN, and the peripheral line pMN may have a width wider than that of the peripheral contact pCT. The peripheral contact pCT and the peripheral line pMN may be formed of a conductive material. The peripheral insulating layer pIS may be formed of an oxide layer that covers the peripheral contact pCT and the peripheral line pMN. Although not shown in the drawing, the lower structure LST may further include structures included in the peripheral circuit 180 of FIG. 1.

The first source layer SL1, the first buffer layer BF1, the sacrificial layer SC, the second buffer layer BF2, and the second source layer SL2 may be sequentially stacked on the lower structure LST. The first and second source layers SL1 and SL2 may be formed of a conductive layer, and the first and second buffer layers BF1 and BF2 may be formed of an insulating layer. For example, the first and second source layers SL1 and SL2 may be formed of a conductive layer such as polysilicon, tungsten, or nickel, and the first and second buffer layers BF1 and BF2 may be formed of an oxide layer such as a silicon oxide layer. The sacrificial layer SC may be formed of the same material as the first and second source layers SL1 and SL2, or may be formed of a material having an etch selectivity different from that of the first and second buffer layers BF1 and BF2. For example, the sacrificial layer SC may be formed of a material with an etch selectivity higher than that of the first and second buffer layers BF1 and BF2 during a wet etching process. The sacrificial layer SC may have a thickness thinner than that of the first source layer SL1, and the second source layer SL2 may have a thickness thinner than that of the sacrificial layer SC. The first and second buffer layers BF1 and BF2 may have the same thickness and may have a thickness thinner than that of the second source layer SL2.

Referring to FIG. 6B, first and second separation openings aOPd and bOPd may be formed in a boundary region of the open contact region OFC and the first and second regions 1R and 2R, and an etching process for forming a central opening OPc in the contact open region OFC may be performed. For example, the first separation opening aOPd exposing a portion of the peripheral insulating layer pIS may be formed by performing an etching process of removing a portion of the second source layer SL2, the second buffer layer BF2, the sacrificial layer SC, the first buffer layer BF1, and the first source layer SL1 positioned in the boundary region of the contact open region OFC and the first region 1R. The second separation opening bOPd exposing a portion of the peripheral insulating layer pIS may be formed by performing an etching process of removing a portion of the second source layer SL2, the second buffer layer BF2, the sacrificial layer SC, the first buffer layer BF1, and the first source layer SL1 positioned in the boundary region of the contact open region OFC and the second region 2R. The etching process for forming the first and second separation openings aOPd and bOPd may be performed simultaneously. In the cross-sectional view cut along A1-A2, the first and second separation openings aOPd and bOPd are spaced apart from each other based on the central axis Ac. However, as in the layout described with reference to FIG. 4, the first and second separation openings aOPd and bOPd extend each other between a region where the third assistance support pattern 3ASP is to be formed and a region where the main support pattern MSP is to be formed.

The central opening OPc may be formed by an etching process of removing a portion of the second source layer SL2, the second buffer layer BF2, the sacrificial layer SC, the first buffer layer BF1, and the first source layer SL1 positioned in the open contact region OFC. The etching process for forming the central opening OPc may be performed simultaneously with the etching process for forming the first and second separation openings aOPd and bOPd, but may be performed at different times in order to improve reliability of a photo lithography process due to a difference in width between the central opening OPc and the first and second separation openings aOPd and bOPd. For example, assuming that an upper width of the central opening OPc is a first width 1W, an upper width of each of the first and second separation openings aOPd and bOPd may have a second width 2W narrower than the first width 1W. When a difference exists in a width of openings adjacent to each other, because distortion may occur in a pattern during a lithography or dry etching process for forming a mask pattern, after the etching process for forming the central opening OPc is performed, the etching process for forming the first and second separation openings aOPd and bOPd may be performed, or after the etching process for forming the first and second separation openings aOPd and bOPd is performed, the etching process for forming the central opening OPc may be performed.

The first and second source layers SL1 and SL2, the sacrificial layer SC, and the first and second buffer layers BF1 and BF2 remaining between the central opening OPc and the first separation opening aOPd may become the first source pattern aSp, and first and second source layers SL1 and SL2, the sacrificial layer SC, and the first and second buffer layers BF1 and BF2 remaining between the central opening OPc and the second separation opening bOPd may become the second source pattern bSp. The first and second source layers SL1 and SL2, the sacrificial layer SC, and the first and second buffer layers BF1 and BF2 remaining in the first region 1R may become a first preliminary pattern aLNp, and the first and second source layers SL1 and SL2, the sacrificial layer SC, and the first and second buffer layers BF1 and BF2 remaining in the second region 2R may become a second preliminary pattern bLNp.

Referring to FIG. 6C, the open region insulating layer OSI and the first and second separation patterns aDP and bDP may be formed by filling the first and second separation openings aOPd and bOPd of FIG. 6B and the central opening OPc with an insulating material ISM. The insulating material ISM may be a silicon oxide layer.

Referring to FIG. 6D, the discharge contact DCC contacting the peripheral line pMN by passing through the open region insulating layer OSI may be formed. For example, a hole exposing a portion of the peripheral line pMN may be formed by exposing a portion of the peripheral insulating layer pIS by etching a central portion of the open region insulating layer OSI and etching the exposed portion of the peripheral insulating layer pIS. A portion of the peripheral line pMN may be exposed through a lower surface of the hole, and a portion of the open region insulating layer OSI and the peripheral insulating layer pIS may be exposed through a side surface. Subsequently, the discharge contact DCC may be formed by filling an inside of the hole with a conductive material. For example, the discharge contact DCC may be formed of a conductive material such as polysilicon, tungsten, or nickel.

Referring to FIG. 6E, a preliminary stack structure pSTK may be formed on the second source layer SL2, the open region insulating layer OSI, and the first and second separation patterns aDP and bDP. The preliminary stack structure pSTK may be formed by alternately stacking the first and second material layers MT1 and MT2. For example, the first material layer MT1 may be formed on the second source layer SL2, the open region insulating layer OSI, first and second etch prevention patterns ESP1 and ESP2, and the discharge contact DCC, and the second material layer MT2 may be formed on the first material layer MT1. The first material layer MT1 may be formed again on the second material layer MT2. In such a method, the preliminary stack structure pSTK including the first and second material layers MT1 and MT2 alternately stacked may be formed. The first material layers MT1 may be an oxide layer, and the second material layers MT2 may be a material with an etch selectivity different from that of the first material layers MT1. For example, the second material layers MT2 may be a nitride layer.

Referring to FIG. 6F, first and second sub openings aOPs and bOPs and first and second main openings aOPm and bOPm exposing a portion of the first and second preliminary patterns aLNp and bLNp or the first and second source patterns aSp and bSp may be formed by etching a portion of the preliminary stack structure pSTK. Although not shown in the drawing, additional openings may be further formed between the first and second main openings aOPm and bOPm. For example, at least one additional opening passing through the first and second material layers MT1 and MT2 stacked on the discharge contact DCC may be further formed. The first and second sub openings aOPs and bOPs may expose a portion of the first and second preliminary patterns aLNp and bLNp by passing through the first and second material layers MT1 and MT2 stacked in the first and second regions 1R and 2R. For example, the first sub opening aOPs may expose a portion of the sacrificial layer SC of the first region 1R, and the second sub opening bOPs may expose a portion of the sacrificial layer SC of the second region 2R. The first and second main openings aOPm and bOPm may expose a portion of the first and second preliminary patterns aLNp and bLNp by passing through the first and second material layers MT1 and MT2 stacked in the first and second regions 1R and 2R. For example, the first main opening aOPm may expose a portion of the sacrificial layer SC of the first source pattern aSp, and the second main opening bOPm may expose a portion of the sacrificial layer SC of the second source pattern bSp. In the drawing, depths of the first sub opening aOPs, the first main opening aOPm, the second main opening bOPm, and the second sub opening bOPs are shown to be the same, but the depths of the openings may be different from each other.

The etching process for forming the first sub opening aOPs, the first main opening aOPm, the second main opening bOPm, and the second sub opening bOPs may be performed as an anisotropic dry etching process. During the etching process, the first and second source patterns aSp and bSp and the first and second preliminary patterns aLNp and bLNp may be used as an etch stop layer. For example, the etching process for forming the first sub opening aOPs, the first main opening aOPm, the second main opening bOPm, and the second sub opening bOPs may be stopped when a portion the first and second source patterns aSp and bSp or the first and second preliminary patterns aLNp and bLNp is exposed. For example, the etching process for forming the first sub opening aOPs, the first main opening aOPm, the second main opening bOPm, and the second sub opening bOPs may be stopped when an element of the sacrificial layer SC is detected.

During the etching process for forming the first sub opening aOPs, the first main opening aOPm, the second main opening bOPm, and the second sub opening bOPs, because the first and second source patterns aSp and bSp and the first and second preliminary patterns aLNp and bLNp may be used as an etch stop layer, over-etching of the etching process may be prevented.

Referring to FIG. 6G, the first and second sub support patterns 1SSP and 2SSP and the first and second main support patterns aMSP and bMSP may be formed in the first sub opening aOPs of FIG. 6G, the first main opening aOPm of FIG. 6F, the second main opening bOPm of FIG. 6F, and the second sub opening bOPs of FIG. 6F. Referring to FIGS. 6G and 3, the first and second sub support patterns 1SSP and 2SSP may be spaced apart from each other in an XY plane, and the first and second main support patterns aMSP and bMSP may extend from each other. The first and second sub support patterns 1SSP and 2SSP and the first and second main support patterns aMSP and bMSP may be formed of an insulating layer. For example, the first and second sub support patterns 1SSP and 2SSP and the first and second main support patterns aMSP and bMSP may be formed of a silicon oxide layer.

Referring to FIG. 6H, first and second slit openings 1OPslt and 2OPslt may be formed in the first and second regions 1R and 2R of the preliminary stack structure pSTK. The first and second slit openings 1OPslt and 2OPslt may be a region dividing memory blocks. Therefore, the first and second slit openings 1OPslt and 2OPslt may pass through the preliminary stack structure pSTK and extend to a portion of the first and second preliminary patterns aLNp and bLNp. For example, a portion of the sacrificial layer SC of the first and second preliminary patterns aLNp and bLNp may be exposed through a lower surface of the first and second slit openings 1OPslt, 2OPslt, and the first and second material layers MT1 and MT2 may be exposed through a side surface. The first slit opening 1OPslt may be formed in a region adjacent to the first sub support pattern 1SSP in the first region 1R, and the second slit opening 2OPslt may be formed in a region adjacent to the second sub support pattern 2SSP in the second region 2R.

Referring to FIG. 6I, an isotropic dry etching process or wet etching process for removing the second material layers MT2 exposed through the first and second slit openings 1OPslt and 2OPslt may be performed. Because the first and second main support patterns aMSP and bMSP have a layout of a linear shape extending from each other (refer to FIG. 3), the second material layers MT2 between the first and second main support patterns aMSP and bMSP are not exposed by the first and second main support patterns aMSP and bMSP. Therefore, the second material layers MT2 between the first and second main support patterns aMSP and bMSP may remain. First recesses REC1 may be formed between the first material layers MT1 from which the second material layers MT2 are removed. The first recesses REC1 means an empty space between the first material layers MT1.

Referring to FIG. 6J, the third material layers MT3 may be formed in the first recesses REC1. The third material layers MT3 may be a conductive material. For example, the third material layers MT3 may be formed of a metal material such as tungsten (W), molybdenum (Mo), cobalt (Co), or nickel (Ni), or a semiconductor material such as silicon (Si) or polysilicon (Poly-Si). When the third material layers MT3 are formed, the stack structure STK configured of the first and third material layers MT1 and MT3 may be formed.

Referring to FIG. 6K, the slit insulating layer SIS may be formed on a side surface of the first and second slit openings 1OPslt and 2OPslt. The slit insulating layer SIS may be an insulating layer. For example, the slit insulating layer SIS may be a silicon oxide layer. After the slit insulating layer SIS is formed, the sacrificial layer SC of FIG. 6J and the first and second buffer layers BF1 and BF2 exposed through a lower surface of the first and second slit openings 1OPslt and 2OPslt may be removed. At this time, because the sacrificial layer SC of FIG. 6J and the first and second buffer layers BF1 and BF2 in the open contact region OFC are not exposed by the first and second separation patterns aDP and bDP, the sacrificial layer SC of FIG. 6J and the first and second buffer layers BF1 and BF2 in the open contact region OFC may remain. A second recess REC2 may be formed between the first and second source layers SL1 and SL2 from which the sacrificial layer SC of FIG. 6J and the first and second buffer layers BF1 and BF2 are removed. The second recess REC2 means an empty space between the first and second source layers SL1 and SL2.

Referring to FIG. 6L, the third source layer SL3 may be formed in the second recess REC2. The third source layer SL3 may be a conductive material. For example, the third source layer SL3 may be formed of the same material as the first and second source layers SL1 and SL2. The first to third source layers SL1 to SL3 that are in contact with each other in the first and second regions 1R and 2R may become the source line SL. For example, the first to third source layers SL1 to SL3 of the first region 1R may be the first source line aSL, and the first to third source layers SL1 to SL3 of the second region 2R may be the second source line bSL. Therefore, the first source line aSL and the first source pattern aSp may be separated from each other by the first separation pattern aDP, and the second source line bSL and the second source pattern bSp may be separated from each other by the second separation pattern bDP. When the third source layer SL3 is filled in the second recess REC2, because the third source layer SL3 may be formed in a portion of a lower portion and a side surface of the first and second slit openings 1OPslt and 2OPslt, an etching process or a cleaning process for removing the third source layer SL3 remaining in the first and second slit openings 1OPslt and 2OPslt may be further performed.

Referring to FIG. 6M, the first and second slit structures 1SLT and 2SLT may be formed in the first and second slit openings 1OPslt and 2OPslt of FIG. 6L. The first slit structure 1SLT may be formed in the first slit opening 1OPslt, and the second slit structure 2SLT may be formed in the second slit opening 2OPslt. The first and second slit structures 1SLT and 2SLT may be formed of an insulating material or a conductive material. When the first and second slit structures 1SLT and 2SLT are formed of a conductive material, the first and second slit structures 1SLT and 2SLT may become a source contact that is in contact with the source line SL. The source contact is a contact that transfers the source voltage to the source line SL. When the first and second slit structures 1SLT and 2SLT are formed of an insulating material, the source line SL may transfer the source voltage through a contact positioned in another region.

Referring to FIG. 6N, a discharge opening OPd exposing a portion of the discharge contact DCC may be formed by removing a portion of the first and second material layers MT1 and MT2 between the first and second main support patterns aMSP and bMSP. An etching process for forming the discharge opening OPd may be performed as an anisotropic dry etching process. The anisotropic dry etching process may be mainly performed in an RIE method or a method applying the RIE method. Plasma is used in the etching process of the RIE method or the method applying the RIE method. A positive ion generated by the plasma may move in a direction perpendicular to an etching target layer and collide with the etching target layer. Therefore, bonding force of a surface of the etching target layer may be weakened. Molecules of a portion where the bonding force is weakened in the etching target layer may be discharged to an outside of a chamber together with a radical moving isotropically. As a depth of the discharge opening OPd increases, the number of positive ions remaining in a lower portion 61 of the discharge opening OPd may increase.

Referring to FIG. 6O, the contact CT may be formed inside the discharge opening OPd of FIG. 6N. The contact CT may be formed of a conductive material. As the contact CT is formed, the upper structure TST including the first to third material layers MT1 to MT3, the first and second slit structures 1SLT and 2SLT, the slit insulating layers SIS, the first and second sub support patterns 1SSP and 2SSP, the first and second main support patterns aMSP and bMSP, and the contact CT may be formed. The positive ions remaining in the discharge opening OPd of FIG. 6N may be discharged to an outside of the memory device through the discharge contact DCC, the peripheral line pMN, the peripheral contact pCT, and the ground terminal GTN.

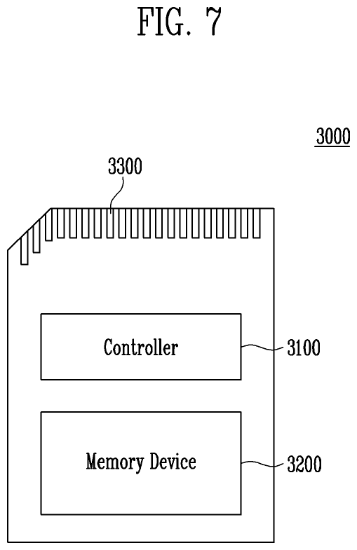

FIG. 7 is a diagram illustrating a memory card system 3000 to which a memory device of the present disclosure is applied.

Referring to FIG. 7, the memory card system 3000 includes a controller 3100, a memory device 3200, and a connector 3300.

The controller 3100 is connected to the memory device 3200. The controller 3100 is configured to access the memory device 3200. For example, the controller 3100 may be configured to control a program, read, or erase operation of the memory device 3200 or to control a background operation. The controller 3100 is configured to provide an interface between the memory device 3200 and a host. The controller 3100 is configured to drive firmware for controlling the memory device 3200. For example, the controller 3100 may include components such as random-access memory (RAM), a processing unit, a host interface, a memory interface, and an error correction circuit.

The controller 3100 may communicate with an external device through the connector 3300. The controller 3100 may communicate with an external device (for example, a host) according to a specific communication standard. For example, the controller 3100 is configured to communicate with an external device through at least one of various communication standards such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, universal flash storage (UFS), Wi-Fi, Bluetooth, and an NVMe. For example, the connector 3300 may be defined by at least one of the various communication standards described above.

The memory device 3200 may include a plurality of memory cells and may be configured identically to the memory device 100 shown in FIG. 1.

The controller 3100 and the memory device 3200 may be integrated into one semiconductor device to configure a memory card. For example, the controller 3100 and the memory device 3200 may be integrated into one semiconductor device to configure a memory card such as a PC card (personal computer memory card international association (PCMCIA)), a compact flash card (CF), a smart media card (SM or SMC), a memory stick, a multimedia card (MMC, RS-MMC, MMCmicro, or eMMC), an SD card (SD, miniSD, microSD, or SDHC), and a universal flash storage (UFS) device.

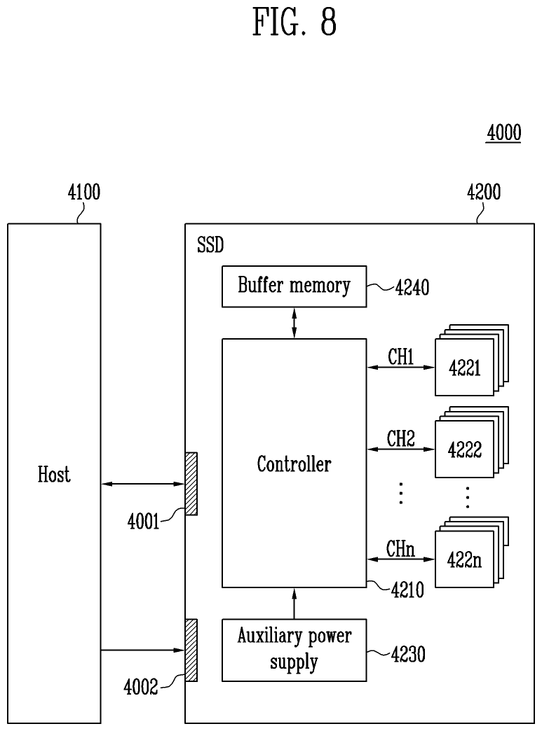

FIG. 8 is a diagram illustrating a solid-state drive (SSD) system 4000 to which a memory device of the present disclosure is applied.

Referring to FIG. 8, the SSD system 4000 includes a host 4100 and an SSD 4200. The SSD 4200 exchanges a signal with the host 4100 through a signal connector 4001 and receives power through a power connector 4002. The SSD 4200 includes a controller 4210, a plurality of memory devices 4221 to 422n, an auxiliary power supply 4230, and buffer memory 4240.

The controller 4210 may control the plurality of memory devices 4221 to 422n in response to the signal received from the host 4100. For example, the signal may be signals based on an interface between the host 4100 and the SSD 4200. For example, the signal may be a signal defined by at least one of interfaces such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, universal flash storage (UFS), Wi-Fi, Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. The plurality of memory devices 4221 to 422n may communicate with the controller 4210 through channels CH1 to CHn.

The auxiliary power supply 4230 is connected to the host 4100 through the power connector 4002. The auxiliary power supply 4230 may receive a power voltage from the host 4100 and charge the power voltage. The auxiliary power supply 4230 may provide a power voltage of the SSD 4200 when power supply from the host 4100 is not smooth. For example, the auxiliary power supply 4230 may be positioned in the SSD 4200 or may be positioned outside the SSD 4200. For example, the auxiliary power supply 4230 may be positioned on a main board and may provide auxiliary power to the SSD 4200.

The buffer memory 4240 operates as buffer memory of the SSD 4200. For example, the buffer memory 4240 may temporarily store data received from the host 4100 or data received from the plurality of memory devices 4221 to 422n, or may temporarily store meta data (for example, a mapping table) of the memory devices 4221 to 422n. The buffer memory 4240 may include volatile memory such as DRAM, SDRAM, DDR SDRAM, and LPDDR SDRAM, or nonvolatile memory such as FRAM, ReRAM, STT-MRAM, and PRAM.

What is claimed is:

1. A memory device comprising:
a discharge contact;
a source pattern surrounding a periphery of the discharge contact and floated;
a source line surrounding a periphery of the source pattern and to which a source voltage is applied;
a separation pattern electrically isolating the source pattern and the source line;
main support patterns positioned on the source pattern;
sub support patterns positioned on the source line; and
a contact positioned on the discharge contact.

2. The memory device of claim 1, further comprising:
a peripheral line contacting a lower portion of the discharge contact;
a peripheral contact contacting a lower portion of the peripheral line; and
a ground terminal contacting a lower portion of the peripheral contact.

3. The memory device of claim 2, wherein the contact, the discharge contact, the peripheral line, the peripheral contact, and the ground terminal are electrically connected to each other.

4. The memory device of claim 2, wherein the peripheral line, the peripheral contact, and the ground terminal are included in a lower structure, and the source line and the source pattern are positioned on the lower structure.

5. The memory device of claim 1, further comprising:
an open region insulating layer positioned between the source pattern and the discharge contact.

6. The memory device of claim 1, wherein the source pattern comprises:
a first source layer;
a first buffer layer on the first source layer;
a sacrificial layer on the first buffer layer;
a second buffer layer on the sacrificial layer; and
a second source layer on the second buffer layer.

7. The memory device of claim 6, wherein the first and second source layers and the sacrificial layer comprise conductive materials, and
the first and second buffer layers comprise insulating materials.

8. The memory device of claim 1, wherein the separation pattern comprises an insulating material.

9. The memory device of claim 1, wherein the main support patterns and the sub support patterns comprise insulating materials.

10. A memory device comprising:
an open region insulating layer extending in a first direction;
a discharge contact included in the open region insulating layer;
a source pattern surrounding an outer surface of the open region insulating layer;
a separation pattern surrounding an outer surface of the source pattern; and
a source line surrounding an outer surface of the separation pattern.

11. The memory device of claim 10, wherein the source pattern is disposed around the open region insulating layer along the first direction and a second direction perpendicular to the first direction, and the source pattern has a linear shape.

12. The memory device of claim 10, wherein the separation pattern is disposed along the first and second directions around the source pattern, and the separation pattern has a linear shape.

13. The memory device of claim 10, wherein the separation pattern comprises an insulating material.

14. The memory device of claim 10, wherein the open region insulating layer, the discharge contact, the source pattern, and the separation pattern are positioned in a connection region designated on a side of a memory block, and
the source line is positioned in the connection region and a cell region adjacent to the connection region.

15. The memory device of claim 14, wherein the source line extends from the connection region to the cell region.

16. The memory device of claim 14, further comprising:
cell plugs positioned in the cell region.

17. The memory device of claim 10, wherein the source pattern is floated.

18. A method of manufacturing a memory device, the method comprising:
stacking source layers on a lower structure;
separating the source layers into a source pattern and a preliminary pattern;
forming a separation pattern between the source pattern and the preliminary pattern;
forming a discharge contact contacting the lower structure in a region spaced apart from the source pattern;
forming a main support pattern positioned on the source pattern and a sub support pattern positioned on the preliminary pattern; and
forming the preliminary pattern as a source line.

19. The method of claim 18, wherein stacking the source layers comprises stacking a first source layer, a first buffer layer, a sacrificial layer, a second buffer layer, and a second source layer on the lower structure.

20. The method of claim 18, wherein separating the source layers into the source pattern and the preliminary pattern comprises performing an etching process for forming a separation opening separating the source layers into the source pattern and the preliminary pattern.

21. The method of claim 20, wherein forming the separation pattern comprises filling the separation opening with an insulating material.

22. The method of claim 18, wherein the main support pattern and the sub support pattern are simultaneously formed.

23. The method of claim 18, wherein forming the main support pattern and the sub support pattern comprises:
forming a preliminary stack structure on the discharge contact, the source pattern, the separation pattern, and the preliminary pattern, after forming the discharge contact;
forming a main opening exposing a portion of the source pattern and a sub opening exposing a portion of the preliminary pattern, by etching a portion of the preliminary stack structure; and
forming the main support pattern in the main opening and forming the sub support pattern in the sub opening by filling the main opening and the sub opening with an insulating material.

24. The method of claim 18, wherein forming the preliminary pattern as the source line comprises:
removing a sacrificial layer included in the preliminary pattern; and
forming the source line including the conductive material and the source layers by filling a region from which the sacrificial layer is removed with a conductive material.
